(19) United States
(12) Patent Application Publication
(10) Pub. No.: US 2025/0177946 A1
(43) Pub. Date: Jun. 5, 2025

(54) A WINDOW ASSEMBLY FOR A CRYSTAL GROWTH ASSEMBLY

(71) Applicant: John Outwater, Bedford, MA (US)

(72) Inventor: John Outwater, Bedford, MA (US)

(21) Appl. No.: 18/969,601

(22) Filed: Dec. 5, 2024

Related U.S. Application Data
(60) Provisional application No. 63/606,280, filed on Dec. 5, 2023.

(51) Int. Cl. B01J 19/06; C01F 7/02

(52) U.S. Cl. CPC B01J 19/06; C01F 7/02

(57) ABSTRACT

The present disclosure teaches a window assembly for a crystal growth system. A die and/or crucible may be placed in insulation. A window in a crystal growth system may be attached to the insulation, allowing visual access to the die or crucible. The presently disclosed window assembly may be secured to the insulation. The window assembly may include an end cap, a window holder, and a sapphire window attached to the window holder. There may be a gap between the sapphire window and a window holder to allow for a flow of argon. The argon may prevent the sapphire window from getting clouded. The end cap may define a slot for the window holder to attach to and move along given the thermal expansion/contraction of the insulation. Alternatively, the window holder may be a thin, flat piece directly screwed to a connecting piece secured to the insulation.

### TECHNICAL FIELD

The present disclosure generally relates to material science and chemical engineering.

### BACKGROUND

In the art of growing sapphire crystals, especially for high-quality sapphire crystals, insulation is often needed surrounding the crucible/die from which the sapphire plates grow. One or more openings in the insulation, typically at the ends, may be needed to allow visual access to the die and control growth. The insulation and die may be surrounded by an atmosphere of argon, an inert gas. The argon gas may flow in the openings in the insulation, past the die, and up a chimney. A circulation pattern may develop, causing most of the gas to flow in one of the openings, cooling that end of the crucible/die excessively, and a substantial and unpredictable thermal gradient along the die may develop as a result, which degrades the growing crystal.

Sapphire windows can be placed over the openings in the insulation to prevent argon entrance. However, the windows tend to cloud over quickly due to vapor from the graphite insulation, the graphite heater, the liquid sapphire, and the tungsten crucible/die. A flow of argon is needed to flush these vapor-phase impurities away from the growing crystal, so blocking the flow through the windows is not desirable.

A window assembly has been developed that flushes argon across the inside face of a window covering an opening of the insulation surrounding the crucible/die. This prevents clouding on the window while allowing a controlled amount of argon to flow through to cleanse the system. The window assembly may fit into an opening in the insulation surrounding the crucible/die and growing crystal. All other gaps in the insulation surrounding this “hot zone” may be sealed with graphite-felt gaskets. As configured, the window and window assembly may also allow visual access to the die during the entire growth cycle. In some embodiments, the crystal growth assembly may have two or more openings. The amount of argon allowed in each of the two or more openings in the insulation is approximately equal. If the argon flows through the two or more windows are imbalanced, a harmful circulation pattern may develop, which may cool one end of the die and disrupt crystal formation.

The present disclosure solves the aforementioned problem—which is to have a thermal imbalance across the forming crystal caused by the difference in flow rates and flow direction in state-of-the-art technologies—by covering the openings with a window having a small gap around its perimeter. The small gap may allow argon exchange, providing a very slight pressure drop between the inside and the outside of the window, which controls the flow rate. It has been discovered that, in typical embodiments, an approximately 30/1000″ (“30 mil”) gap may provide the optimal balance of flow control without choking off the flow. The gap size may also vary; for example, a 100-mil gap may be effective in one alternative embodiment. If the gaps are too wide, too much argon may flow in at rates that cannot be precisely controlled and cause the above-noted thermal imbalance. On the other hand, a gap too small between the window and the graphite holder may block the argon flow excessively. The presently disclosed window assembly may keep the window spacing at a desired distance of approximately 30 mils, or 100 mils in one alternative embodiment. As noted above, the insulation about the crucible may be fully sealed and may move and/or deform slightly due to thermal expansion/contraction. Accordingly, the window may be able to move up and down slightly to accommodate the thermal expansion/contraction.

To conclude, one or more windows and the holders thereof may be useful components to include in a crystal growth assembly to (1) allow visual access to the die and (2) control a flow of argon in the assembly. Also, because the insulation may expand and/or contract slightly under a change of temperature, the window assembly cannot be entirely rigid but needs to allow for some degree of flexibility so that the window can move slightly with the expansion/contraction of the insulation.

### SUMMARY

The present disclosure teaches a window assembly for a crystal growth assembly, comprising: a window holder secured to insulation surrounding a die or crucible of a crystal growth assembly; wherein the window holder includes one or more protrusions; a sapphire window mounted onto the one or more protrusions; wherein the one or more protrusions define a gap between the sapphire window and the window holder; wherein the gap allows for a flow of argon in and out of the sapphire window.

In some embodiments, the window assembly further includes: an end cap secured to the insulation; wherein, the end cap defines a tunnel allowing visual access to the die or crucible; wherein, the end cap defines a slot; wherein, the window holder is attached to the slot and able to move along the slot with thermal expansion or contraction of the insulation.

In some embodiments, the window holder is a thin, flat piece screwed to a connecting piece secured to the insulation; wherein the connecting piece defines a tunnel allowing visual access to the die or crucible.

In some embodiments, the end cap is made of rigid graphite felt.

In some embodiments, the window holder is made of graphite.

In some embodiments, the window holder is rectangular.

In some embodiments, the gap is 30 mils wide.

In some embodiments, the gap is 100 mils wide.

In some embodiments, the slot is vertical.

In some embodiments, the crystal growth assembly is for sapphire.

The present disclosure also teaches a crystal growth assembly, comprising: an insulation surrounding a die or crucible for crystal growth; one or more window assemblies attached to the insulation; wherein, each of the one or more window assemblies includes: a window holder secured to the insulation; wherein the window holder includes one or more protrusions; a sapphire window mounted onto the one or more protrusions; wherein one or more protrusions define a gap between the sapphire window and the window holder; wherein the gap allows for a flow of argon in and out of the sapphire window.

In some embodiments, each of the one or more window assemblies further includes: an end cap secured to the insulation; wherein the end cap defines a tunnel allowing visual access to the die or crucible; wherein, the end cap defines a slot; wherein, the window holder is attached to the slot and able to move along the slot with thermal expansion or contraction of the insulation.

In some embodiments, the window holder is a thin, flat piece screwed to a connecting piece secured to the insulation; wherein the connecting piece defines a tunnel allowing visual access to the die or crucible.

In some embodiments, the end cap is made of rigid graphite felt.

In some embodiments, the window holder is made of graphite.

In some embodiments, the window holder is rectangular.

In some embodiments, the gap is 30 mils wide.

In some embodiments, the gap is 100 mils wide.

In some embodiments, the slot is vertical.

In some embodiments, the crystal growth assembly is for sapphire.

### BRIEF DESCRIPTION OF THE DRAWINGS

The present disclosure is further illustrated by way of exemplary embodiments, which are described in detail through the accompanying drawings. These embodiments are not limiting, and in these embodiments, the same numbering indicates the same structure, wherein:

FIG. 1A is an isometric diagram showing an assembly for crystal growth with the presently disclosed window assembly, according to some embodiments of the present disclosure;

FIG. 1B is an isometric view diagram of the presently disclosed window assembly, according to some embodiments of the present disclosure;

FIG. 1C is an end-view diagram thereof;

FIG. 1D is an end-view diagram thereof;

FIG. 1E is a top-view diagram thereof;

FIG. 1F is a cross-sectional side-view diagram thereof;

FIG. 1G is another cross-sectional side-view diagram thereof;

FIG. 2 is an isometric view diagram of the window assembly;

FIGS. 2A-B are enlarged isometric view diagrams of components consisting of the presently disclosed window assembly, according to some embodiments of the present disclosure.

FIGS. 2C-D are isometric view diagrams showing components in the window assembly, according to alternative embodiments of the present disclosure.

### DETAILED DESCRIPTION

In order to more clearly illustrate the technical solutions of the embodiments of the present disclosure, the accompanying drawings for the description of the embodiments are described below. Obviously, the accompanying drawings in the following description are only some examples or embodiments of the present disclosure, and it is possible for a person of ordinary skill in the art to apply the present disclosure to other similar scenarios in accordance with these accompanying drawings without creative labor. Unless obviously obtained from the context or the context illustrates otherwise, the same numeral in the drawings refers to the same structure or operation.

It should be understood that the terms “system,” “device,” “unit,” and/or “module” are used herein as a way to distinguish between different components, elements, parts, sections, or assemblies at different levels. However, if other words may achieve the same purpose, the terms may be replaced with alternative expressions.

As indicated in the present disclosure and in the claims, unless the context clearly suggests an exception, the words “one,” “a,” “a kind of,” and/or “the” do not refer specifically to the singular but may also include the plural. In general, the terms “include” and “comprise” suggest only the inclusion of clearly identified steps and elements, which do not constitute an exclusive list, and the method or device may also include other steps or elements.

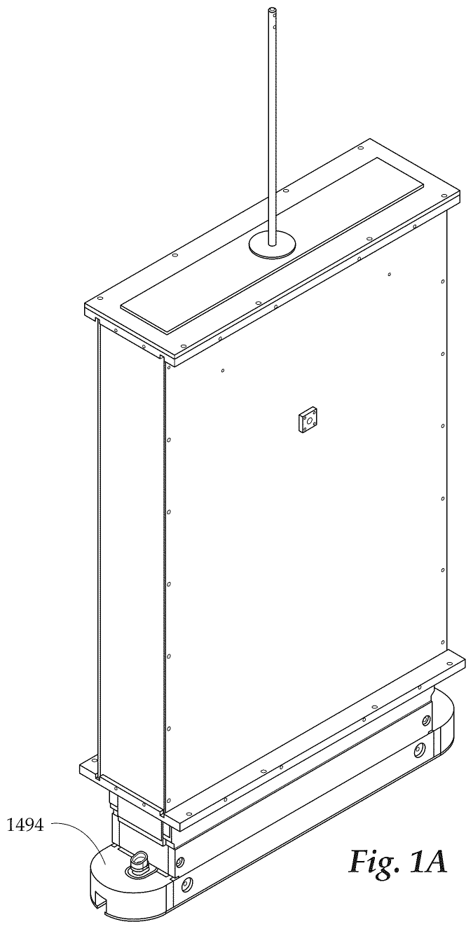

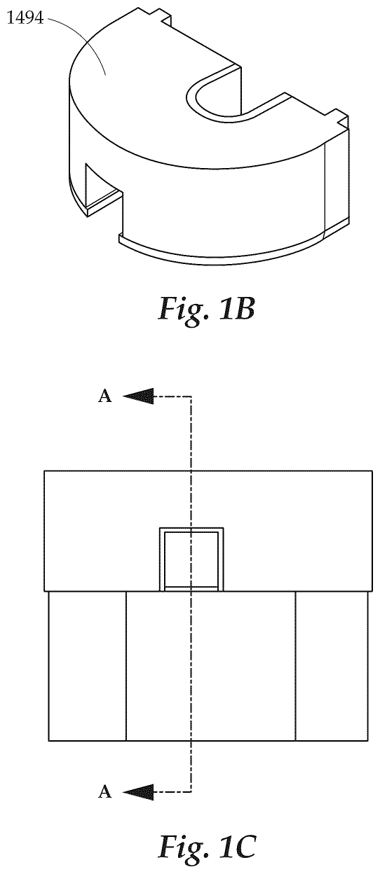

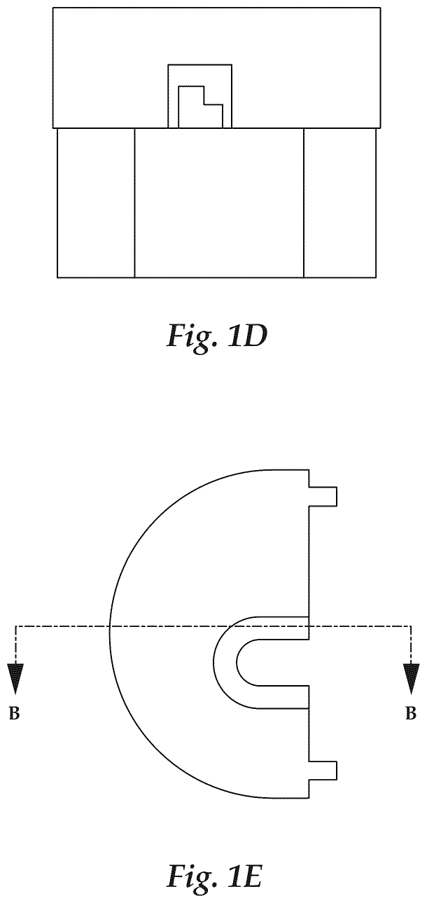

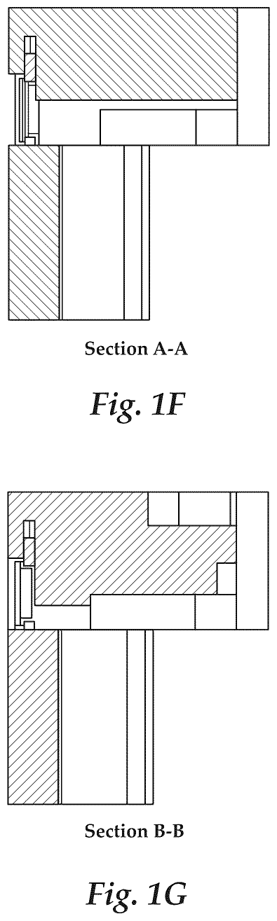

FIG. 1A is an isometric diagram showing an assembly for crystal growth with the presently disclosed window assembly, according to some embodiments of the present disclosure; FIG. 1B is an isometric view diagram of the presently disclosed window assembly, according to some embodiments of the present disclosure; FIG. 1C is a front-view diagram thereof; FIG. 1D is a back-view diagram thereof; FIG. 1E is a top-view diagram thereof; FIG. 1F is a cross-sectional side-view diagram thereof; FIG. 1G is another cross-sectional side-view diagram thereof.

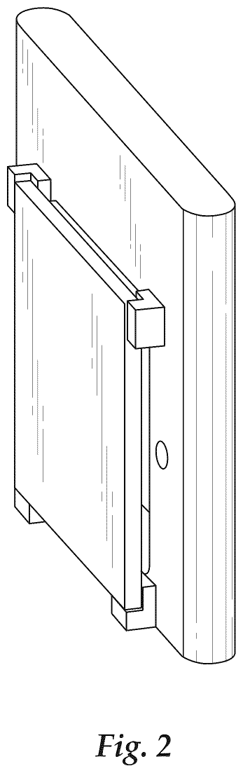

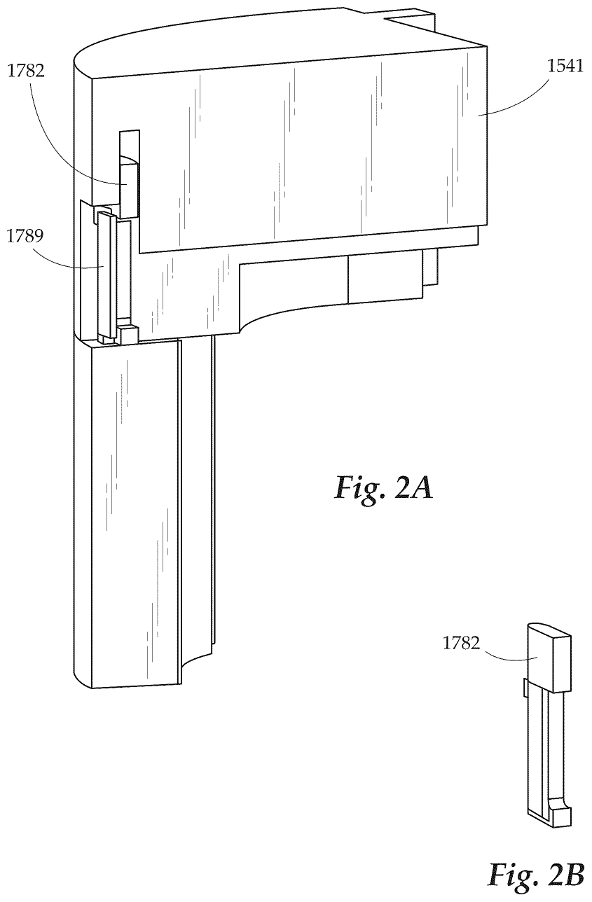

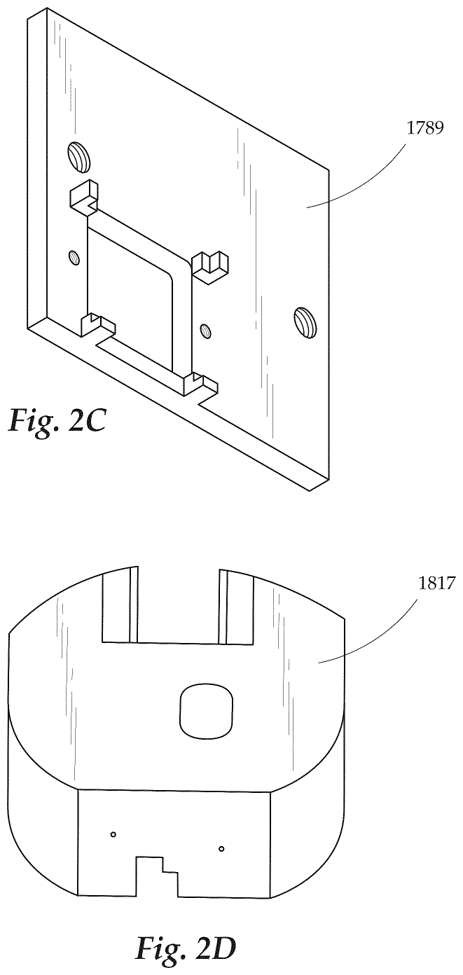

FIG. 2 is an isometric view diagram of the window holder and the window;

FIGS. 2A-B are enlarged isometric view diagrams of components consisting of the presently disclosed window assembly, according to some embodiments of the present disclosure.

As illustrated in FIG. 1, in some embodiments, presently disclosed window assemblies 1494 may be placed at both ends of an elongated insulation surrounding the crucible/die. In some embodiments, the window assemblies 1494 may be secured to both ends of the insulation. The word “secured” in this context means firmly attached or fastened, directly or indirectly, to something, ensuring no gaps or spaces are left, thereby preventing air or other substances from passing through. In some embodiments, the crucible/die may be located at the bottom of a crystal growth assembly. As discussed in the background section, the windows, and window assemblies thereof, may serve the dual purposes of allowing visual access to the crucible/die, and controlling argon flow. In some embodiments, the presently disclosed window assemblies 1494 placed in the same crystal growth assembly may be identical, so that the argon flow may be balanced. As illustrated in FIG. 1 and FIGS. 1A-E, in some embodiments, the presently disclosed window assembly 1494 may be shaped as a semi-cylindrical segment of a cylinder. In some embodiments, the number(s), size(s), and shape(s) of the presently disclosed window assembly(ies) 1494 may be adjusted according to the specifications of the insulation and/or the crystal growth assembly the window assembly(ies) are used with.

In some embodiments, as illustrated in FIG. 2, the presently disclosed window assembly 1494 may include three parts: an end cap 1541, a window holder 1789, and a window 1782. In some embodiments, the end cap 1541 may be made of rigid graphite felt insulation, and the window holder 1789 may be made of graphite. In some embodiments, the window 1782 may be made of sapphire. In some embodiments, the window 1782 may be made of other transparent materials, such as alumina, spinel, quartz, silicon, etc.

In some embodiments, the end cap 1541 may form a body of the presently disclosed window assembly 1494. In some embodiments, the end cap 1541 may generally be in the shape of a semi-cylindrical segment of a cylinder. It may include a solid top part for holding the window 1782 and defining a tunnel for visual access to the die/crucible, and a bottom part shaped as a column, for providing support to the solid top part. In some embodiments, a cross-section of the tunnel may not be of the same shape as the window 1782 but may be in a shape of an “L” and may have a smaller area than the window 1782. This is because, the cross-section of the tunnel may be as small as possible to minimize heat loss, but still provide sufficient visual access. In some embodiments, the tunnel may not be straight, and mirrors may be included in the tunnel to allow visual access through the tunnel. In some embodiments, a side surface of the end cap 1541 may contain one or more protrusions, recessions, and/or slots, via which the end cap 1541 may be attached to the insulation.

In some embodiments, the top part of the end cap 1541 may define a slot, to accommodate the window holder 1789. In some embodiments, the slot may be vertical. As discussed in the background section, insulation about the crucible may be fully sealed and may move due to thermal expansion/contraction. Hence, the window holder 1789 may be able to move upward/downward along the slot to accommodate the thermal expansion and/or contraction. Alternatively, the slot may be horizontal, and window holder 1789 may move sideways along the slot.

In some embodiments, the window holder 1789 may be a rectangular or square piece larger than the window 1782. The window holder 1789 may have a hole or aperture in the middle to allow visual access through the window 1782. In some embodiments, the window holder 1789 may have one or more protrusions holding the window 1782 in place and may also define a gap between the window and the window assembly. In some embodiments, the window holder 1789 may have four protrusions at the four corners of the window 1782. As discussed above in the background section, the small gap may allow argon in, providing a very slight pressure drop between the inside and the outside of the window 1782, which controls the flow rate. Also, as discussed above, in some embodiments, the gap may be approximately 30/1000″ (“30 mil”) to achieve optimal flow control.

In some embodiments, the window holder 1789 and the end cap 1541 may be 3D-printed.

FIGS. 2C-D are isometric view diagrams showing components in the window assembly, according to alternative embodiments of the present disclosure.

Per FIG. 2C, in some alternative embodiments, the window holder 1789 may be a thin, flat piece directly secured to the connecting piece 1817 (shown in FIG. 2D) using a plurality of screws. The end cap 1541 may be omitted from the window assembly, allowing for a simplified design. The connecting piece 1817 may be secured to one of the two ends of the insulation. The connecting piece 1817 may also include a tunnel allowing visual access to the die/crucible, similar to the end cap 1541. However, the connecting piece 1817 does not have a slot allowing slight vertical movements of the window holder 1789 as the end cap 1541 does. In these embodiments, the screws may be made of graphite or other heat-resisting materials. In these embodiments, the window holder 1789 may be rectangular. The window holder 1789 may be made of graphite. In these embodiments, the window holder 1789 may also have a hole or aperture in the middle to allow visual access through the window 1782. The window holder 1789 may or may not match the shape and size of the window 1782. In these embodiments, the window holder 1789 may have one or more protrusions holding the window 1782 in place and may also define a gap between the window and the window assembly. In some embodiments, the window holder 1789 may have four protrusions at the four corners of the window 1782. As discussed above in the background section, the small gap may allow argon in, providing a very slight pressure drop between the inside and the outside of the window 1782, which controls the flow rate. In one embodiment, the gap may be approximately 100 mils. In some embodiments, the window 1782 may be attached to the window holder using screws. In some embodiments, the screws may be made of tungsten.

In some embodiments, a camera may be placed outside the window 1782 to take pictures or a real-time video showing the crucible or die.

In some embodiments, a person with ordinary skills in the art may adapt the presently disclosed window assembly for a crystal growth assembly for other crystals besides sapphire, such as ruby, quartz, yttrium aluminum garnet (YAG), spinel, etc.

Furthermore, unless explicitly stated in the claims, the use of order, numbers, letters, or other names for processing elements and sequences are not intended to limit the order of the processes and methods of the present disclosure. While various examples have been discussed in the disclosure as currently considered useful embodiments of the invention, it should be understood that such details are provided for illustrative purposes only. The appended claims are not limited to the disclosed embodiments, and instead, the claims are intended to cover all modifications and equivalent combinations within the scope and essence of the embodiments disclosed in the present disclosure. For example, although the described system components may be implemented through a hardware device, they may also be realized solely through a software solution, such as installing the described system on an existing processing or mobile device.

Similarly, it should be noted that, for the sake of simplifying the presentation of embodiments disclosed in the present disclosure and aiding in understanding one or more embodiments of the present disclosure, various features have been sometimes combined into a single embodiment, drawing, or description. However, this manner of disclosure does not imply that the features required by the claims are more than the features mentioned in the claims. In fact, the features of the embodiments are less than all the features of the single embodiment disclosed in the foregoing disclosure.

In some embodiments, numeric values describing the composition and quantity of attributes are used in the description. It should be understood that such numeric values used for describing embodiments may be modified with qualifying terms such as “about,” “approximately” or “generally”. Unless otherwise stated, “about,” “approximately” or “generally” indicates that a variation of ±20% is permitted in the described numbers. Accordingly, in some embodiments, the numerical parameters used in the disclosure and claims are approximations, which can change depending on the desired characteristics of the individual embodiment. In some embodiments, the numerical parameters should take into account a specified number of valid digits and employ a general manner of bit retention. Although the numerical ranges and parameters used in some embodiments of the present disclosure to confirm the breadth of the range are approximations, in specific embodiments, such numerical values are set as precisely as practicable.

With respect to each of the patents, patent applications, publications of patent applications, and other material, such as articles, books, specifications, publications, documents and the like, cited in the present disclosure, the entire contents thereof are hereby incorporated herein by reference. Application history documents that are inconsistent with the contents of the present disclosure or that create conflicts are excluded, as are documents (currently or hereafter appended to the present disclosure) that limit the broadest scope of the claims of the present disclosure. It should be noted that in the event of any inconsistency or conflict between the descriptions, definitions, and/or use of terminology in the materials appended to the present disclosure and the contents described herein, the descriptions, definitions, and/or use of terminology in the present disclosure shall prevail.

In closing, it should be understood that the embodiments described in the present disclosure are used only to illustrate the principles of the embodiments of the present disclosure. Other deformations may also fall within the scope of the present disclosure. Therefore, by way of example and not limitation, alternative configurations of the embodiments disclosed in the present disclosure may be considered consistent with the teachings of the present disclosure. Accordingly, the embodiments described in the present disclosure are not limited to the explicitly introduced and described embodiments in the present disclosure.

What is claimed is:

1. A window assembly for a crystal growth assembly, comprising:
a window holder secured to insulation surrounding a die or crucible of a crystal growth assembly;
wherein the window holder includes one or more protrusions;
a sapphire window mounted onto the one or more protrusions;
wherein the one or more protrusions define a gap between the sapphire window and the window holder;
wherein the gap allows for a flow of argon past the sapphire window.

2. The window assembly of claim 1, further comprising:
an end cap secured to the insulation;
wherein, the end cap defines a tunnel allowing visual access to the die or crucible;
wherein, the end cap defines a slot;
wherein, the window holder is attached to the slot and able to move along the slot with thermal expansion or contraction of the insulation.

3. The window assembly of claim 1, wherein the window holder is a thin, flat piece screwed to a connecting piece secured to the insulation;
wherein the connecting piece defines a tunnel allowing visual access to the die or crucible.

4. The window assembly of claim 2, wherein the end cap is made of rigid graphite felt.

5. The window assembly of claim 1, wherein the window holder is made of graphite.

6. The window assembly of claim 1, wherein the window holder is rectangular.

7. The window assembly of claim 2, wherein the gap is 30 mils wide.

8. The window assembly of claim 3, wherein the gap is 100 mils wide.

9. The window assembly of claim 1, wherein the slot is vertical.

10. The window assembly of claim 1, wherein the crystal growth assembly is for sapphire.

11. A crystal growth assembly, comprising:
an insulation surrounding a die or crucible for crystal growth;
one or more window assemblies attached to the insulation;
wherein, each of the one or more window assemblies includes:
a window holder secured to the insulation;
wherein the window holder includes one or more protrusions;
a sapphire window mounted onto the one or more protrusions;
wherein one or more protrusions define a gap between the sapphire window and the window holder;
wherein the gap allows for a flow of argon past the sapphire window.

12. The crystal growth assembly of claim 11, wherein each of the one or more window assemblies further includes:
an end cap secured to the insulation;
wherein the end cap defines a tunnel allowing visual access to the die or crucible;
wherein, the end cap defines a slot;
wherein, the window holder is attached to the slot and able to move along the slot with thermal expansion or contraction of the insulation.

13. The crystal growth assembly of claim 11, wherein the window holder is a thin, flat piece screwed to a connecting piece secured to the insulation;
wherein the connecting piece defines a tunnel allowing visual access to the die or crucible.

14. The crystal growth assembly of claim 12, wherein the end cap is made of rigid graphite felt.

15. The crystal growth assembly of claim 11, wherein the window holder is made of graphite.

16. The crystal growth assembly of claim 11, wherein the window holder is rectangular.

17. The crystal growth assembly of claim 12, wherein the gap is 30 mils wide.

18. The crystal growth assembly of claim 13, wherein the gap is 100 mils wide.

19. The crystal growth assembly of claim 11, wherein the slot is vertical.

20. The crystal growth assembly of claim 11, wherein the crystal growth assembly is for sapphire.
